(19) United States
(12) Patent Application Publication
(10) Pub. No.: US 2009/0134394 A1
(43) Pub. Date: May 28, 2009

(54) CRYSTAL SILICON ARRAY, AND MANUFACTURING METHOD OF THIN FILM TRANSISTOR

(76) Inventors: Kazufumi AZUMA, Yokohama-shi (JP); Shigeyuki Shimoto, Konosu-shi (JP); Masakiyo Matsumura, Kamakura-shi (JP); Takahiko Endo, Okegawa-shi (JP); Yukio Taniguchi, Matsudo-shi (JP); Tomoya Kato, Mobara-shi (JP)

Correspondence Address: OBLON, SPIVAK, MCCLELLAND MAIER & NEUSTADT, P.C., 1940 DUKE STREET, ALEXANDRIA, VA, 22314, US

(21) Appl. No.: 12/277,732

(22) Filed: Nov. 25, 2008

(30) Foreign Application Priority Data
Nov. 27, 2007 (JP) 2007-305325

(51) Int. Cl. H01L 29/786; H01L 21/336

(52) U.S. Cl. 257/66; 438/149; 257/E29.273; 257/E21.412

(57) ABSTRACT

A crystal silicon array includes a crystallized unit region obtained by crystallizing at least a part of a non-single crystal semiconductor film. The crystallized unit region includes at least one square two-dimensional crystal portion having a size of 7 μm square or more, and at least one needle crystal portion having a grain length of 3.5 μm or more.

### CROSS-REFERENCE TO RELATED APPLICATIONS

This application is based upon and claims the benefit of priority from prior Japanese Patent Application No. 2007-305325, filed Nov. 27, 2007, the entire contents of which are incorporated herein by reference.

### BACKGROUND OF THE INVENTION

1. Field of the Invention

The present invention relates to a crystal silicon array, and a manufacturing method of a thin film transistor. More particularly, it relates to a manufacturing method of a thin film transistor for use in a liquid crystal display, an organic EL display or the like, and a crystal silicon array suitable for the formation of the thin film transistor.

2. Description of the Related Art

A driving circuit of a display such as a liquid crystal display is usually formed by an amorphous semiconductor film formed on a glass substrate. With the enlargement of an IT market, information to be handled is digitized, and the processing of the information is speeded up. Hence, the high image quality of such a display has been demanded. To satisfy this demand, for example, there is known a means which forms a switching transistor for switching respective pixels by using a crystal semiconductor so that the switching can be speeded up and the high image quality can be achieved.

As a technique of crystallizing an amorphous silicon layer formed on the glass substrate, an excimer laser annealing process (the ELA process) is known. Crystals obtained by this ELA process have very small grain diameters of about 0.1 μm. Therefore, the transistor cannot be formed only in one single crystal, and a thin film transistor (TFT) has to be formed in a crystallized region constituted of a plurality of single crystals. In the case of the thus formed thin film transistor, a number of crystal grain boundaries are included in a channel region of this transistor. Consequently, the thin film transistor has a low field effect mobility of about 100 cm²/Vs, which is noticeably poor as compared with that of an MOS transistor (more than 800 cm²/Vs) formed on single-crystal silicon (Si).

To improve the mobility of the thin film transistor, various investigations have heretofore been made. For example, in a sequential lateral solidification (SLS) process, a phenomenon referred to as super lateral growth is utilized to obtain crystals having large grain diameters in excess of 1 μm (e.g., Appl. Phys. Lett., Vol. 69, p. 2864 to 2866, 1996). The crystals having such large grain diameters can improve the mobility of the thin film transistors formed in the respective crystals, but they have a disadvantage that the growth directions of the crystals fluctuate to make the characteristics of the thin film transistors uneven.

To eliminate this disadvantage, elongate crystals having grain boundaries mainly in parallel with a channel direction are disclosed (e.g., Jpn. J. Appl. Phys., Vol. 41, L311, 2002). According to the above elongate crystals, the problems of the mobility and the uneven characteristics can be solved. However, in a future circuit such as a so-called system-on-glass circuit in which a peripheral circuit is formed on one glass plate, or in a current driving type device, it is demanded that the unevenness of the characteristics is further decreased.

To further improve the mobility of the thin film transistor and decrease the unevenness of the characteristics, it is preferable to employ a structure in which a plurality of transistors are arranged in one crystal grain, that is, a pair transistor structure. As the size of one crystal grain necessary for this structure, a size of about 5 μm square which has heretofore been reported is insufficient.

### BRIEF SUMMARY OF THE INVENTION

An object of the present invention is to provide a crystal silicon array including a plurality of crystals having such large grain diameters that a plurality of thin film transistors can be arranged in one crystal grain.

According to one aspect of the present invention, there is provided a crystal silicon array having a crystallized unit region obtained by crystallizing at least a part of a non-single crystal semiconductor film,

wherein the crystallized unit region includes at least one square two-dimensional crystal portion having a size of 7 μm square or more, and at least one needle crystal portion having a grain length of 3.5 μm or more.

According to another aspect of the present invention, there is provided a manufacturing method of a thin film transistor by positioning a transistor device so that at least one channel is put in the two-dimensional crystal portion of the crystal silicon array according to the one aspect of the invention.

In the present application, each crystallized unit region of a crystal silicon array obtained by crystallizing an amorphous silicon thin film includes a two-dimensional crystal portion having such a size including a square region of 7 μm square or more, and a needle crystal portion having a grain length of 3.5 μm or more. Therefore, when the thin film transistors are formed by positioning transistor devices in the two-dimensional crystal portion, for example, a pair transistor structure can be realized in which a plurality of transistors are arranged in one crystal grain. In other words, according to the present invention, it is possible to realize a crystal silicon array including crystals having such large grain diameters that permit arranging the plurality of thin film transistors in one crystal grain.

Additional objects and advantages of the invention will be set forth in the description which follows, and in part will be obvious from the description, or may be learned by practice of the invention. The objects and advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate embodiments of the invention, and together with the general description given above and the detailed description of the embodiments given below, serve to explain the principles of the invention.

FIG. 1 is a diagram for explaining the size of a crystal grain necessary for realizing a pair transistor structure;

FIG. 2 is a diagram schematically showing a structural example of a crystal silicon array according to the present invention;

FIGS. 3A and 3B are diagrams showing a light intensity distribution and a transient temperature change in a case where a phase modulation element is used, and FIGS. 3C and 3D are diagrams showing a light intensity distribution and a transient temperature change in a case where a metal mask is used;

FIG. 4 is a diagram schematically showing a structure of a crystallization apparatus usable in forming the crystal silicon array according to an embodiment of the present invention;

FIG. 5 is a diagram schematically showing an internal structure of an illumination system of FIG. 4;

FIG. 6 is a diagram schematically showing an internal structure of a waveform control section for use in the illumination system of FIG. 5;

FIG. 7A is a diagram showing the temperature distribution of the section of a sample immediately after irradiated with laser at a time when the waveform control section is not used, and FIG. 7B is a diagram showing the temperature distribution of the section of a sample immediately after irradiated with laser at a time when the waveform control section is used;

FIG. 8 is a diagram schematically showing a structure of a part of a light modulation element for use in the crystallization apparatus of FIG. 4;

FIG. 9 is a diagram showing a light intensity distribution formed on a processing target substrate by using the light modulation element of FIG. 8;

FIG. 10 is a diagram schematically showing the behavior of crystallization at a time when a non-single crystal semiconductor film is irradiated with light having the light intensity distribution shown in FIG. 9;

FIG. 11 is an SEM diagram showing that a two-dimensional crystal portion is formed from a single growth nucleus in the present embodiment;

FIG. 12 is an SEM diagram of a crystal silicon array including crystals having large grain diameters formed in the present embodiment; and

FIGS. 13A to 13E are step sectional views showing steps of manufacturing an electronic device by using the crystallization apparatus of the present embodiment.

### DETAILED DESCRIPTION OF THE INVENTION

Hereinafter, a size of each crystal grain necessary for realizing a pair transistor structure and a basic concept of the present invention will be described, prior to the detailed description of an embodiment of the present invention. For example, in a crystal liquid display, a display panel is practically used in which an amorphous silicon film is formed on a glass substrate as an insulator, and a thin film transistor circuit is then formed by this amorphous silicon film. With digitization in an electron industry field, a high speed operation has been demanded, and the thin film transistor circuit of the high speed operation formed on a polycrystal silicon thin film has been put to practical use.

However, the polycrystal silicon thin film is constituted of polycrystal grains, and hence a plurality of grain boundaries or boundary lines are present in a channel region of each of the formed thin film transistors. The number of the boundary lines present in the channel region of each thin film transistor varies, and therefore, when holes and electrons move, grain boundaries of the micro crystal grains become barriers. Consequently, mobility characteristics of the thin film transistors vary, with the result that such characteristics of the thin film transistor circuit as designed cannot be obtained.

To solve this problem, the present applicant has developed an industrial crystallization technology in which each crystal grain larger than the channel region of the thin film transistor is positioned in a desired position to grow the grain. This crystallization technology is a technology of modulating pulse laser light from excimer laser into an arrangement pattern of a light intensity distribution in the state of a plurality of inverse peak patterns to irradiate the amorphous silicon film, whereby the amorphous silicon film in an irradiated region is melted to form regions of the crystals having large grain diameters in a temperature lowering period after the block of the pulse laser light.

In the thus formed regions of the crystals having the large grain diameters, transistor devices are positioned to form the thin film transistors, whereby the thin film transistor circuit having uniform characteristics can be formed. Examples of the thin film transistor circuit include pair transistor circuits such as a CMOS circuit and a multivibrator circuit, and in each of such circuits, the thin film transistors which perform opposite operations are connected to each other to form a pair. In this pair of transistors, it is demanded that the thin film transistors which perform the opposite similar operations be formed in the crystallized regions having the same characteristics.

On the other hand, it has been found that when the crystallized regions are formed by the above crystallization technology, different defect patterns are generated in the respective crystal grains. Therefore, it has been found that when one thin film transistor is formed in each crystal grain to form the pair transistor circuit, the pair transistor circuit having desired characteristics cannot be formed. Furthermore, it has been found that the thin film transistors which perform the opposite operations have to be formed in the same crystal grain. It has also been found that the crystallized region necessary for forming the thin film transistors for the pair transistor circuit has a size of 7 μm square or more as described hereinbelow.

At present, mobilities of a usual low-temperature polysilicon are about 100 cm²/Vs in an n-channel (n-ch), and about 50 cm²/Vs in a p-channel (p-ch). Channel sizes corresponding to this mobility usually are a width Wn=about 5 μm in the n-ch, and a width Wp=about 10 μm in the p-ch. In a crystal silicon array formed in the present invention, the mobilities are improved to about 300 cm²/Vs in the n-ch, and about 100 cm²/Vs in the p-ch. As dimensions of the channels corresponding to such mobilities, as shown in FIG. 1, a width Wn=about 2 μm in the n-ch, and a width Wp=about 6 μm in the p-ch are considered to be adequate.

When the p-channel having a width Wp=6 μm or more and the n-channel having a width Wn=2 μm or more are arranged in one crystal grain, the channels are vertically or laterally arranged in accordance with a purpose, and therefore a square grain having a size of 7 μm square or more is necessary as shown in FIG. 1, because protrusions are formed in a boundary portion between the adjacent crystals owing to the collision of the crystals, and hence the channel needs to be arranged as much as about 0.5 μm away from the boundary portion.

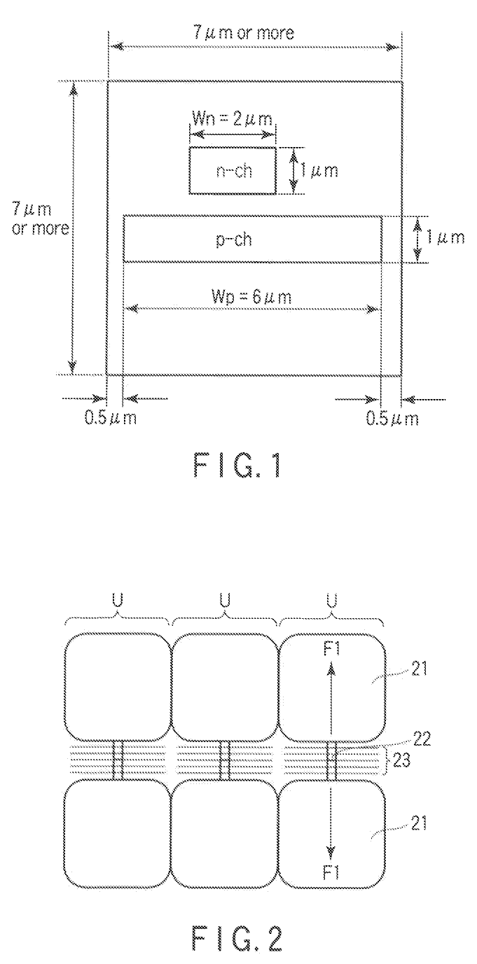

FIG. 2 is a diagram schematically showing a structural example of the crystal silicon array according to the present invention. Referring to FIG. 2, in the crystal silicon array of the present invention obtained by crystallizing a non-single crystal semiconductor thin film, for example, an amorphous silicon thin film, each crystallized unit region U includes a pair of two-dimensional crystal portions 21 each having such a size as to include a square region of 7 μm square, a micro crystal portion 22 having a length of 0.2 μm or more, and a group of needle crystal portions 23 having grain lengths of 3.5 μm or more.

It has been found that the micro crystal portion 22 for allowing the growth of the square crystal grain of 7 μm square or more needs to have a length of 0.2 μm or more. Each two-dimensional crystal portion 21 is formed by the growth of one crystal nucleus, and has a main growth direction of the crystals as shown by an arrow F1. The micro crystal portion 22 is formed between the pair of two-dimensional crystal portions 21, and has a length of 0.2 μm or more along the main growth direction F1. One group of the needle crystal portions 23 are formed between the pair of spaced two-dimensional crystal portions 21 in the main growth direction F1 by the growth along a direction crossing the main growth direction F1 of the two-dimensional crystal portion 21 at right angles.

To stably prepare the two-dimensional crystal portion 21 having a large area, investigation of enlarging a process margin is necessary. We have investigated a light intensity distribution by use of a phase modulation element to develop a technique by which only one nucleus grows in a two-dimensional region. According to this technique, as described later, even when a light intensity fluctuates, a single growth nucleus can appear in any portion of the micro crystal portion 22 having a length of 0.2 μm or more, and to secure this appearance, a micro crystal portion region having a length of 0.2 μm or more is provided.

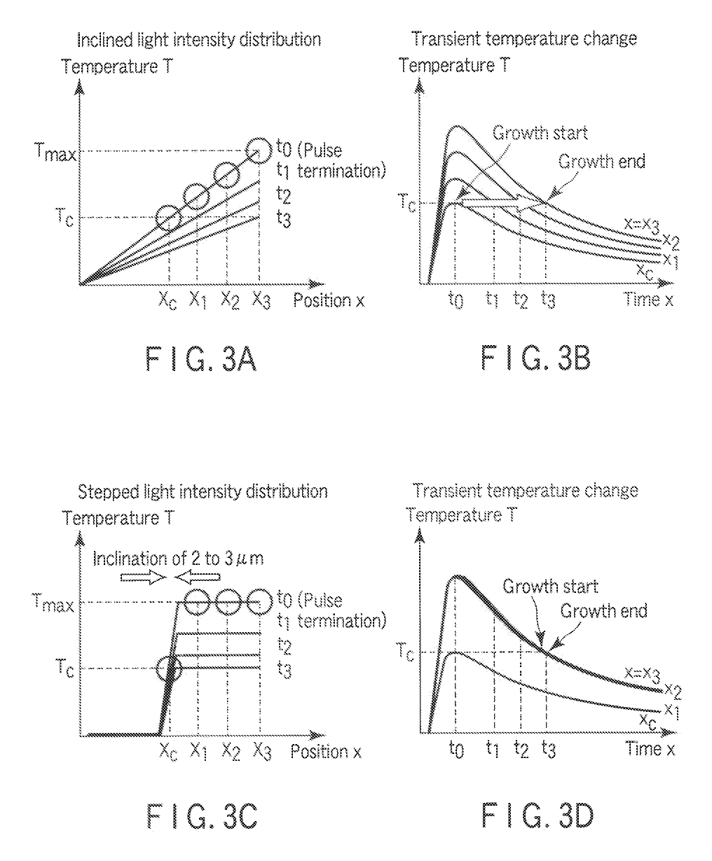

In the present invention, laser crystallization is performed so that a crystallizing position can two-dimensionally be controlled, by a method of controlling the light intensity distribution of laser light with the phase modulation element. In a case where the phase modulation element is used, the light intensity distribution can more precisely be controlled, as compared with a case where a metal mask is used. Moreover, as understood from FIGS. 3A to 3D, in the case where the metal mask is used, efficiency of extending crystal grain lengths is poor in principle, as compared with the case where the phase modulation element is used.

That is, as shown in FIGS. 3A and 3B, when the phase modulation element is used, an inclined light intensity distribution can be controlled. Therefore, a crystallization temperature Tc is reached in a position Xc away from a position X₃ where the temperature of the substrate most rises at a time t₀ when laser irradiation ends (a pulse termination time). Then, when crystal growth starts, the crystal growth is possible for a time until the temperature at the position X₃ reaches the crystallization temperature Tc, that is, for a time of (t₃-t₀).

On the other hand, as shown in FIGS. 3C and 3D, when the metal mask is used, a stepped light intensity distribution is formed. Therefore, even when it is tried to start the crystal growth at the crystallization temperature Tc in the position Xc, the crystal growth cannot be started owing to a high temperature in a position X₁ right adjacent to the position Xc. When the metal mask is used, the temperatures substantially simultaneously lower to the crystallization temperature Tc from the position X₁ to the position X₃. Therefore, the crystal grow is limited to a very short time. As understood from the above, when the phase modulation element is used to control a light intensity gradient, the crystal grow is possible for a long time.

On the other hand, for usual laser crystallization, pulse laser such as excimer laser is used, and a pulse width per pulse is a short time of about 30 ns. To form the crystals having large grain diameters, it is necessary to lengthen a laser pulse waveform. For this purpose, for example, the laser light is effectively split into a plurality of light beams to create an optical path difference. In practice, as described later, the pulse width can be extended as much as about ten times by use of a multiple reflective optical system in which a plurality of partial reflective plates are arranged.

As described above, to obtain the crystals having large grain diameters of 7 μm square or more, the laser pulse width needs to be extended so that the single growth nucleus (a crystal nucleus) can be generated to grow the crystals from the nucleus over a sufficient time. Moreover, in the present invention, to stably generate the single growth nucleus with satisfactory reproducibility even in a case where the light intensity distribution fluctuates, the elongate micro crystal portions 23, that is, nucleus forming portions are provided.

In consequence, even when the light intensity fluctuates, the single growth nucleus is surely generated in any portion of the elongate nucleus forming portion 23, and the crystals can two-dimensionally grow from this nucleus. In the present invention, to secure an environment where the single growth nucleus can be generated and further secure a long distance of the crystal growth as described above, the pulse width has to be extended. In a phase modulation process, a crystal growth time in a lateral direction can be extended. When optimum long pulse light corresponding to this is applied, the crystal silicon array having large grain diameters can be realized.

The embodiment of the present invention will be described with reference to the drawings.

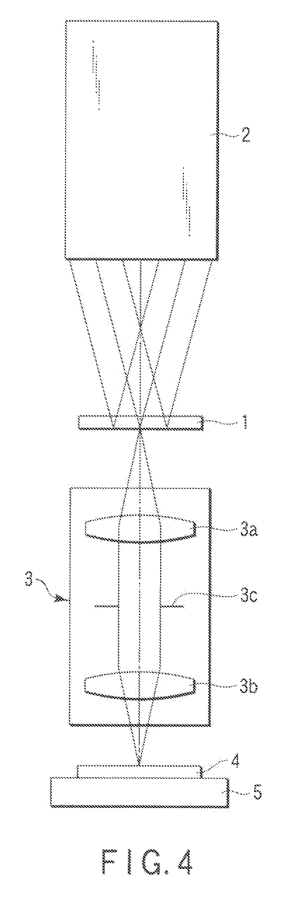

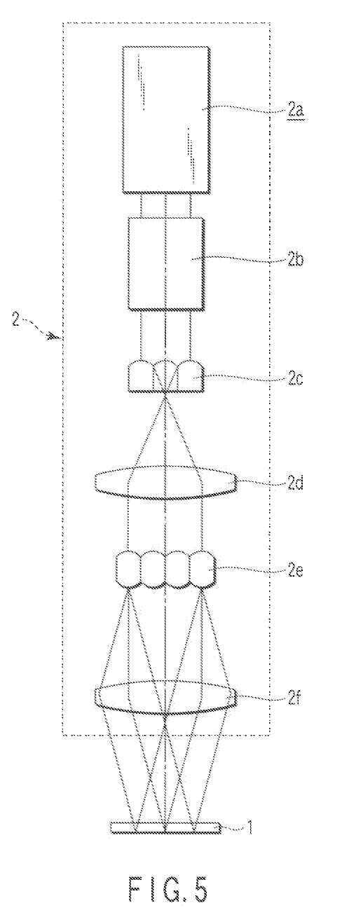

FIG. 4 is a diagram schematically showing a structure of a crystallization apparatus usable in forming the crystal silicon array according to the embodiment of the present invention, and FIG. 5 is a diagram schematically showing an internal structure of an illumination system of FIG. 4. Referring to FIGS. 4 and 5, the crystallization apparatus of the present embodiment includes an illumination system 2, a light modulation element 1 for modulating the phase of an incident light flux emitted from this illumination system to form a light flux having a predetermined light intensity distribution, an image forming optical system 3, and a substrate stage 5 for holding a processing target substrate 4.

A structure and a function of the light modulation element 1 will be described later. The illumination system 2 includes an XeCl excimer laser light source 2a which supplies the pulse laser light having a wavelength of, for example, 308 nm. As this light source 2a, another appropriate light source such as a KrF excimer laser light source or a YAG laser light source having a function of emitting an energy ray which fuses the processing target substrate 4 may be used. The laser light supplied from the light source 2a enters a first fly-eye lens 2c via a waveform control section 2b. A structure and a function of the waveform control section 2b will be described alter.

Thus, a plurality of small light sources are formed on a rear focal plane of the first fly-eye lens 2c, and an incidence plane of a second fly-eye lens 2e is illuminated with the light fluxes from the plurality of small light sources via a first condenser optical system 2d in a superimposing manner. Consequently, more small light sources are formed on a rear focal plane of the second fly-eye lens 2e than those on the rear focal plane of the first fly-eye lens 2c. The light modulation element 1 is illuminated with the light fluxes from the plurality of small light sources formed on the rear focal plane of the second fly-eye lens 2e via a second condenser optical system 2f in a superimposing manner.

The first fly-eye lens 2c and the first condenser optical system 2d constitute a first homogenizer. This first homogenizer uniforms the laser light emitted from the light source 2a in relation to an incidence angle on the light modulation element 1. Moreover, the second fly-eye lens 2e and the second condenser optical system 2f constitute a second homogenizer. This second homogenizer uniforms the laser light having the uniformed incidence angle from the first homogenizer in relation to a light intensity at each in-plane position on the light modulation element 1.

The emitted laser light subjected to the phase modulation by the light modulation element 1 enters the processing target substrate 4 via the image forming optical system 3. Here, a phase pattern plane of the light modulation element 1 and the processing target substrate 4 are arranged at optically conjugate positions of the image forming optical system 3. In other words, the processing target substrate 4 (strictly an irradiation target surface of the processing target substrate 4) is set to a plane (an image plane of the image forming optical system 3) which is optically conjugate with the phase pattern plane of the light modulation element 1.

The image forming optical system 3 includes, for example, a positive lens group 3a, a positive lens group 3b, and an aperture stop 3c arranged between these lens groups. A size of an opening portion (a light transmitting portion) of the aperture stop 3c (i.e., an image-side numerical aperture NA of the image forming optical system 3) is set to generate a necessary light intensity distribution on the semiconductor film (the irradiation target surface) of the processing target substrate 4. The image forming optical system 3 may be a refractive optical system, a reflective optical system, or a refractive/reflective optical system.

The processing target substrate 4 is obtained by forming a lower layer insulating film, a non-single crystal semiconductor thin film and an upper layer insulating film in this order on a glass substrate. More specifically, in the present embodiment, the processing target substrate 4 is formed by successively forming a base insulating film, a non-single crystal semiconductor film (e.g., an amorphous silicon film), and a cap film on, for example, a liquid crystal display glass plate by a chemical vapor deposition (CVD) method. Each of the base insulating film and the cap film may be an insulating film, for example, an SiO₂ film. The base insulating film prevents foreign particles, for example, Na in the glass substrate from entering the amorphous silicon film when the amorphous silicon film directly comes into contact with the glass substrate, and further prevents heat of the amorphous silicon film from being directly transmitted to the glass substrate.

The amorphous silicon film is a semiconductor film to be crystallized. The cap film is heated by a part of a light beam which enters the amorphous silicon film, and stores heat having a temperature realized by this heating. A temperature in a high-temperature portion on an irradiation target surface of the amorphous silicon film is relatively rapidly lowered when the incidence of the light beam is interrupted. However, this thermal storage effect alleviates this temperature-down gradient, and promotes lateral crystal growth with large grain diameters. The processing target substrate 4 is positioned and held at a predetermined position on the substrate stage 5 by a vacuum chuck or an electrostatic chuck.

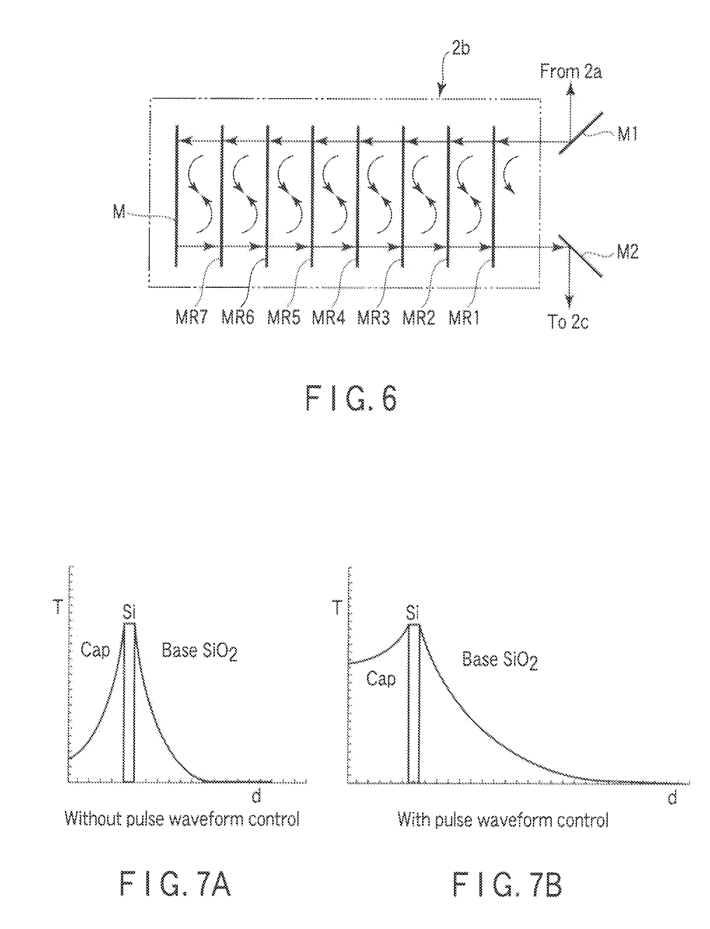

FIG. 6 is a diagram schematically showing an internal structure of the waveform control section 2b shown in FIG. 5. In the present embodiment, laser light from the XeCl excimer laser light source 2a (not shown in FIG. 6) having a wavelength of, for example, 308 nm and a half-value full width of about 25 ns is guided into the waveform control section 2b via a first mirror M1 (omitted in FIG. 5). The waveform control section 2b has seven partial transmission mirrors MR1 to MR7 successively arranged in a row at predetermined intervals, and one total reflection mirror M. Reflection ratios R1 to R7 of the partial transmission mirrors MR1 to MR7 are R1=0.40, R2=0.07, R3=0.085, R4=0.095, R5=0.125, R6=0.17 and R7=0.25 in order from a position close to a light incidence side (the right side in FIG. 6) along an optical path.

The total reflection mirror M is installed behind the partial transmission mirror MR7 having the reflection ratio R7. An optical path length between the adjacent mirrors is 4500 mm. In FIG. 6, the partial transmission mirrors MR1 to MR7 are linearly arranged, but a total reflection concave mirror for suitably setting a distance between these optical elements and the optical path may be provided, and a partial transmission mirror may be provided between the total reflection concave mirrors. Moreover, a flat-plate mirror may be used instead of the concave mirror.

The transmission and reflection of the pulse laser light by the seven partial transmission mirrors MR1 to MR7 are performed as follows. That is, the light transmitted through the first partial transmission mirror MR1 enters the second partial transmission mirror MR2, and the light reflected by the first partial transmission mirror MR1 is guided to the first fly-eye lens 2c (not shown in FIG. 6) via the mirror M2. The light transmitted through the second partial transmission mirror MR2 enters the third partial transmission mirror MR3, and the light reflected by the second partial transmission mirror MR2 is guided to the first fly-eye lens 2c via the first partial transmission mirror MR1.

The light transmitted through the n-th partial transmission mirror MRn enters the n+1-th partial transmission mirror MRn+1, and the light reflected by the n-th partial transmission mirror is guided to the first fly-eye lens 2c via n−1-th, n−2-th, . . . first partial transmission mirrors MRn−1, MRn−2, . . . MR1. It is to be noted that the light transmitted through the seventh partial transmission mirror MR7 is reflected by the total reflection mirror M, and is guided to the first fly-eye lens 2c via the seventh, sixth, first partial transmission mirrors MR7, MR6, . . . MR1.

When such transmission and reflection by the partial transmission mirrors are repeated, a pulse width is expanded, and the irradiation time of the processing target substrate 4 is extended. Consequently, at a time when the temperature of the silicon film reaches the maximum temperature, heat more than that in a case where the pulse width is not expanded is diffused from the silicon film to the cap film and the base SiO₂ layer, and these film temperatures rise. In consequence, the cooling speed of the silicon film is retarded, the fusing time of the silicon film extends, and a crystal growth distance extends. Consequently, the crystals having large grain diameters can be obtained.

On the other hand, in a case where such control of the waveform of the pulse laser light is not performed, an only small amount of heat is diffused in the cap film and the base SiO₂ layer at the time when the temperature of the silicon film reaches the maximum temperature. Therefore, the cooling speed of the silicon film is high as compared with a case where the waveform is controlled. Therefore, the fusing time of the silicon film shortens, and the crystal growth distance shortens. To show these behaviors, FIGS. 7A and 7B show the temperature distributions of the cross sections of samples immediately after irradiated with the laser light. FIG. 7A shows a case where the waveform of the pulse laser light is not controlled, and FIG. 7B shows a case where the waveform of the pulse laser light is controlled, respectively.

FIG. 8 is a diagram schematically showing one example of a structure of the light modulation element 1 shown in FIG. 4. The light modulation element 1 has a repeated structure of a first strip-like region 1A and a second strip-like region 1B along one direction (a horizontal direction in the drawing). In the first strip-like region 1A, a rectangular region 1Aa shown by a hatched portion in the drawing or a square cell (a unit region) has a phase value of −60 degrees, and a region 1Ab shown by a blank portion in the drawing has a phase value of 0 degree. In the second strip-like region 1B, a rectangular region shown by a hatched portion in the drawing or a square cell (a unit region) 1Ba has a phase value of +60 degrees, and a region 1Bb shown by a blank portion in the drawing has a phase value of 0 degree.

As described above, with respect to the phase value of 0 degree as a reference, +60 degrees indicate phase advance, and −60 degrees indicate phase delay. Moreover, the pitches of the strip-like regions 1A and 1B are 5 μm in terms of the image plane of the image forming optical system 3. In other words, in the strip-like regions 1A and 1B, the square cells (the unit regions) having a size of 1 μm×1 μm in terms of the image plane of the image forming optical system 3 are vertically and laterally arranged, for example, 5 cells×11 cells are densely arranged. Here, the size of 1 μm×1 μm of each cell in terms of the image plane of the image forming optical system 3 is set to a size smaller than the radius of the point image distribution range of the image forming optical system 3.

In the first strip-like region 1A, the occupying area ratio (i.e., an area ratio between the regions 1Aa and 1Ab in each cell) of the region 1Aa in each cell changes along the pitch direction of the strip-like region (a direction crossing a boundary line between the strip-like regions 1A and 1B at right angles: the horizontal direction in the drawing), and the ratio changes along a pitch orthogonal direction crossing the strip-like region pitch direction at right angles (a direction along the boundary line between the strip-like regions 1A and 1B: a vertical direction in the drawing). More specifically, the occupying area ratio of the region 1Aa along the strip-like region pitch direction is smallest in the center of the strip-like region 1A, and increases toward both ends of the region.

The occupying area ratio of the region 1Aa along the pitch orthogonal direction of the strip-like region is largest in the center of the strip-like region 1A, and decreases toward both the ends of the region. In other words, in the strip-like region 1A, a first specific place having the largest occupying area ratio of the region 1Aa in the cell as the unit region is present adjacent to the grain boundary of boundary line, the occupying area ratio of the region 1Aa decreases away from the first specific place along the pitch orthogonal direction, and the ratio decreases away from the first specific place in the pitch direction.

Similarly, in the strip-like region 1B, the occupying area ratio (i.e., an area ratio between the regions 1Ba and 1Bb in each cell) of the region 1Ba in each cell changes along the pitch direction of the strip-like region, and the ratio changes along the pitch orthogonal direction of the strip-like region. More specifically, the occupying area ratio of the region 1Ba along the strip-like region pitch direction is smallest in the center of the strip-like region 1B, and increases toward both the ends of the region. On the other hand, the occupying area ratio of the region 1Ba along the pitch orthogonal direction of the strip-like region is largest in the center of the strip-like region 1B, and decreases toward both the ends of the region. In other words, in the strip-like region 1B, a second specific place having the largest occupying area ratio of the region 1Ba in the cell as the unit region is present adjacent to the boundary line, the occupying area ratio of the region 1Ba decreases away from the second specific place along the pitch orthogonal direction, and the ratio decreases away from the second specific place in the pitch direction.

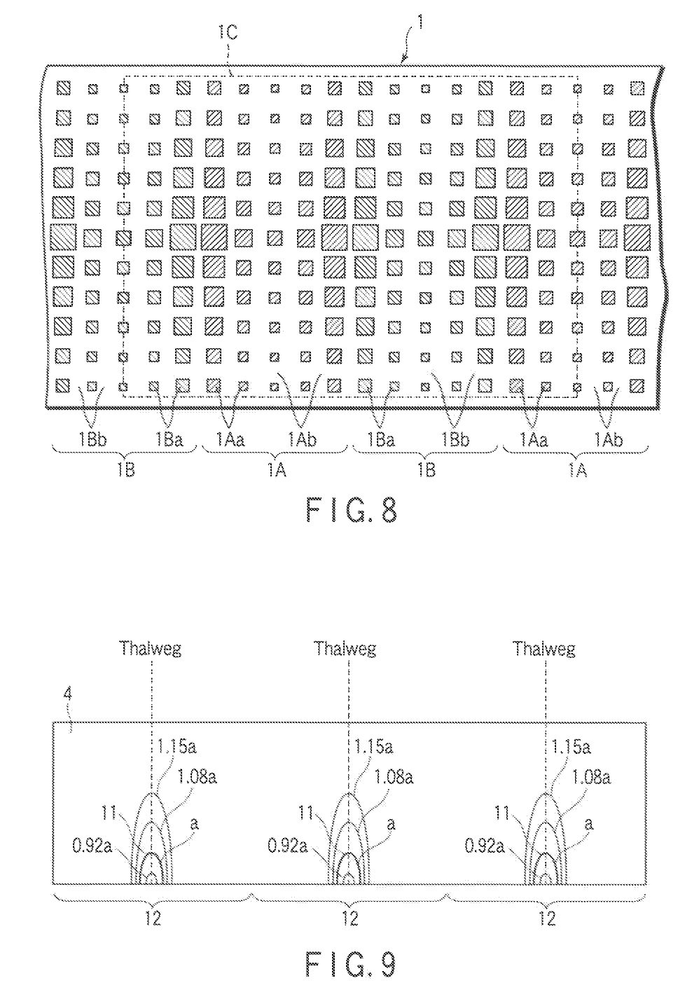

In the present embodiment, a light intensity distribution is formed as shown in FIG. 9 on the processing target substrate 4 by use of the light modulation element 1 shown in FIG. 8. In FIG. 9, the light intensity distribution formed on the processing target substrate 4 is shown by the contour line (i.e., the iso-intensity curve) of light intensity in accordance with the upper region of about half of a rectangular region 1C shown by a broken line in FIG. 8. In FIG. 9, to clarify the drawing, the drawing of the iso-intensity curve corresponding to a light intensity larger than 1.15a is omitted.

In FIG. 9, a light intensity a corresponds to the fusing temperature of a non-single crystal semiconductor film on the processing target substrate 4, an iso-intensity curve (the iso-intensity curve corresponding to an outer edge of a non-fusing region on the non-single crystal semiconductor film and corresponding to a crystal start point) 11 having the light intensity a has an elliptic shape elongated in the vertical direction of the drawing, and the curvature radius of the curve has a minimum value of 0.2 μm in the upper and lower ends of the drawing. Thus, the light modulation element 1 shown in FIG. 8 is designed so that the processing target substrate (the non-single crystal semiconductor film) 4 can be irradiated with light having such a light intensity distribution that a part of the iso-intensity curve 11 corresponding to the outer edge of the non-fusing region has a curvature radius of 0.3 μm or less. Additionally, even a part of the iso-intensity curve of a light intensity of 0.92a or the iso-intensity curve of a light intensity of 1.08a has a curvature radius of 0.3 μm or less.

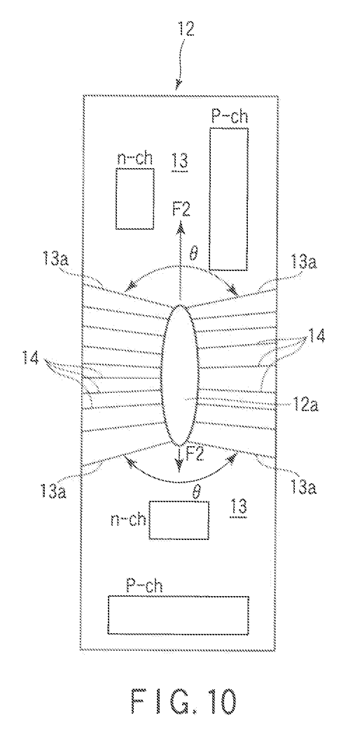

When the non-single crystal semiconductor film of the processing target substrate 4 is irradiated with the light having the light intensity distribution shown in FIG. 9, as schematically shown in FIG. 10, a non-fusing region 12a corresponding to the elliptic iso-intensity curve 11 of the light intensity a is formed in one crystallized unit region 12 on the non-single crystal semiconductor film. Then, two-dimensional crystal grains 13 grow from crystal nuclei formed near the upper and lower ends of the non-fusing region 12a in the drawing, respectively, with a large radiation angle θ of, for example, 100 degrees or more along an arrow F2 in the drawing. That is, crystal grain boundaries 13a radially extend from the crystal nuclei so that the large radiation angle θ of, for example, 100 degrees or more is formed.

Needle elongate crystal grains 14 linearly extending along the horizontal direction of the drawing grow from a plurality of crystal nuclei formed on the right and left sides of the non-fusing region 12a in the drawing. The two-dimensional crystal grains 13 of FIG. 10 correspond to the two-dimensional crystal portions 21 of FIG. 2, the non-fusing region 12a of FIG. 10 corresponds to the micro crystal portion 22 of FIG. 2, the needle crystal grains 14 of FIG. 10 correspond to the needle crystal portions 23 of FIG. 2, and the arrow F2 of FIG. 10 corresponds to the main growth direction F1 of the two-dimensional crystal portion 21 of FIG. 2.

In each of the two-dimensional crystal grains 13, channels of an n-channel transistor and a p-channel transistor are formed. In this case, as shown in the drawing, two channels formed in the upper two-dimensional crystal grain 13 are formed to extend in a crystal growth direction (the F2 direction), and two channels formed in the lower two-dimensional crystal grain 13 are formed to extend in a direction crossing the crystal growth direction at right angles. Such channels are arbitrarily arranged, and the channels formed in all or some of the two-dimensional crystal grains may extend in the crystal growth direction or the direction crossing the crystal direction at right angles.

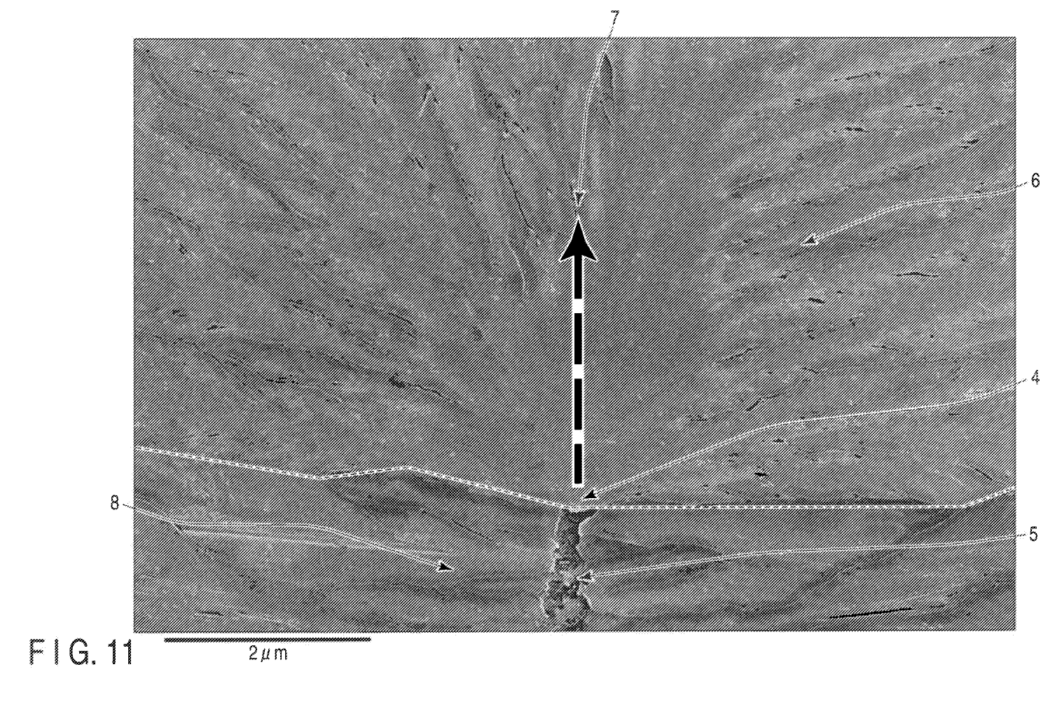

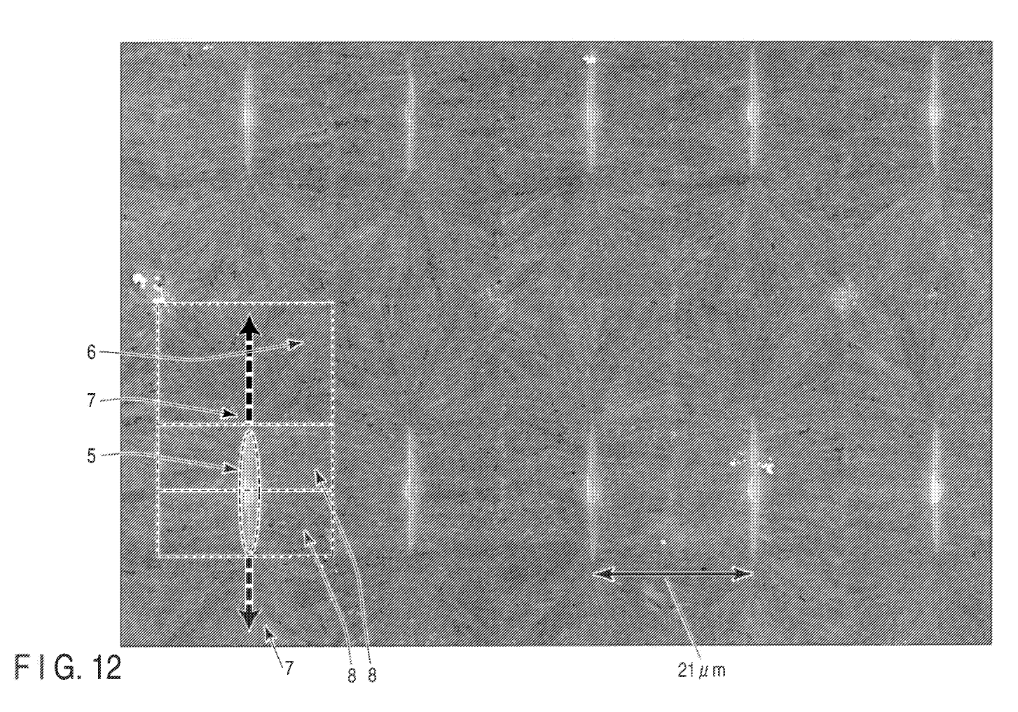

FIG. 11 is an SEM diagram showing that the two-dimensional crystal portion is formed from a single growth nucleus in the present embodiment. FIG. 12 is an SEM diagram showing a crystal silicon array including crystals having large grain diameters as formed in the present embodiment. In FIG. 11, an arrow 4 indicates a position where a single nucleus is generated, an arrow 5 indicates a vertically elongate nucleus generating region (corresponding to the micro crystal portion 22 of FIG. 2), an arrow 6 indicates a two-dimensional crystal region (corresponding to the two-dimensional crystal portion 21 of FIG. 2), an arrow 7 indicates the main growth direction of a two-dimensional crystal, and an arrow 8 indicates a needle crystal region (corresponding to the needle crystal portions 23 of FIG. 2) grown from the nucleus generating region shown by the arrow 5 in a lateral direction.

In FIG. 12, reference numeral 5 is a vertically elongate nucleus generating region (corresponding to the micro crystal portion 22 of FIG. 2), reference numeral 6 is a two-dimensional crystal region (corresponding to the two-dimensional crystal portion 21 of FIG. 2), arrows 7 indicate the main growth direction of the two-dimensional crystal, and reference numerals 8 are needle crystal regions (corresponding to the needle crystal portions 23 of FIG. 2) grown from the nucleus generating region 5 in the lateral direction. It is seen from FIG. 12 that the two-dimensional crystal portion having a square shape of about 21 μm square is formed.

As described above, according to the present embodiment, an array of two-dimensional crystal portions having a size incorporating a 7 μm square region can stably be formed. Therefore, in a case where the thin film transistor is formed so that the transistor is aligned with the two-dimensional crystal portions of the crystal silicon array formed by the present embodiment, for example, the pair transistor structure is realized, the mobility of the thin film transistor is improved, and the characteristic fluctuations can further be decreased.

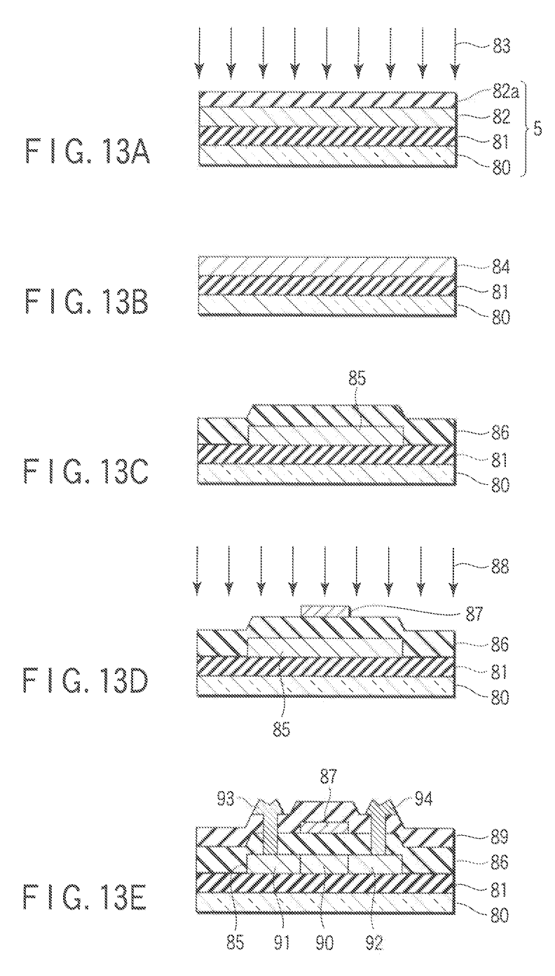

FIGS. 13A to 13E are step sectional views showing steps of preparing an electronic device in a crystallized region by using the crystallization apparatus of the present embodiment. As shown in FIG. 13A, a processing target substrate 5 is prepared by sequentially forming a base film 81 (e.g., a laminated film containing SiN having a film thickness of 50 nm and SiO₂ having a film thickness of 100 nm), an amorphous semiconductor film 82 (e.g., a semiconductor film containing Si, Ge or SiGe having a film thickness of about 50 nm to 200 nm), and a cap film 82a (e.g., an SiO₂ film having a film thickness of 30 nm to 300 nm or the like) on a transparent insulating substrate 80 (e.g., a substrate of alkali glass, quartz glass, plastic, or polyimide) by a chemical vapor deposition method or a sputtering method. Then, a predetermined region or a plurality of regions on the upper surface (the irradiation target surface) of the amorphous semiconductor film 82 is or are irradiated with laser light 83 (e.g., KrF excimer laser light, XeCl excimer laser light or the like) by using the crystallization apparatus according to the present embodiment.

In this manner, as shown in FIG. 13B, a polycrystal semiconductor film or a single-crystallized semiconductor film 84 having crystals with large grain diameters is formed. Next, the cap film 82a is removed from the semiconductor film 84 by etching. Afterward, as shown in FIG. 13C, the polycrystal semiconductor film or the single-crystallized semiconductor film 84 is processed into, for example, an island-shaped semiconductor film 85 serving as a region in which a thin film transistor is formed, by using a photolithography technology as shown in FIG. 13C. An SiO₂ film having a film thickness of 20 nm to 100 nm is formed as a gate insulating film 86 on the surface of the semiconductor film by using the chemical vapor deposition method or the sputtering method. Moreover, as shown in FIG. 13D, a gate electrode 87 (e.g., silicide, MoW or the like) is formed on the gate insulating film, and the gate electrode 87 is used as a mask to implant impurity ions 88 (phosphor in case of an N-channel transistor, or boron in case of a P-channel transistor) into the semiconductor film 85. Afterward, an annealing treatment (e.g., at 450° C. for one hour) is carried out in a nitrogen atmosphere to activate the impurities, thereby forming a source region 91 and a drain region 92 in the island-shaped semiconductor film 85 on both sides of a channel region 90. Next, as shown in FIG. 13E, an interlayer insulating film 89 is formed, contact holes are formed in this interlayer insulating film, and then a source electrode 93 and a drain electrode 94 to be respectively connected to the source region 91 and the drain region 92 are formed in the holes.

In the above-mentioned steps, the transistor is formed in accordance with the positions of the large crystals of the polycrystal semiconductor film or the single-crystallized semiconductor film 84 formed in the steps shown in FIGS. 13A and 13B, that is, so that the channel 90 is disposed in the crystal grain. By the above steps, a polycrystal transistor or a thin film transistor (TFT) in the single-crystallized semiconductor can be formed. The thus manufactured polycrystal transistor or single-crystallized transistor can be applied to a drive circuit of a liquid crystal display (a display) or an EL (electroluminescence) display, an integrated circuit of a memory (an SRAM or a DRAM) or a CPU or the like.

In the above embodiment, the crystallization of the amorphous silicon thin film as the non-single crystal semiconductor thin film has been described. However, even when the present invention is applied to the crystallization of a polycrystal semiconductor thin film constituted of crystal grains having a size of 7 μm square or less, a similar effect can be obtained.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A crystal silicon array having a crystallized unit region obtained by crystallizing at least a part of a non-single crystal semiconductor film,
wherein the crystallized unit region includes at least one square two-dimensional crystal portion having a size of 7 μm square or more, and at least one needle crystal portion having a grain length of 3.5 μm or more.

2. The crystal silicon array according to claim 1, wherein the two-dimensional crystal portion is formed by growth of one crystal nucleus, and has a main growth direction of crystals.

3. The crystal silicon array according to claim 2, wherein the needle crystal portion is formed by growth along a direction crossing the main growth direction at right angles.

4. The crystal silicon array according to claim 2, wherein the needle crystal portion is formed between a pair of spaced two-dimensional crystal portions in the main growth direction.

5. The crystal silicon array according to claim 4, wherein the crystallized unit region further includes a micro crystal portion formed between the pair of two-dimensional crystal portions and having a length of 0.2 μm or more along the main growth direction.

6. The crystal silicon array according to claim 1, which is crystallized by irradiating the amorphous silicon thin film with laser light having a predetermined light intensity distribution.

7. The crystal silicon array according to claim 1, further comprising a thin film transistor having a p-channel formed in the two-dimensional crystal portion; and a thin film transistor having an n-channel.

8. The crystal silicon array according to claim 7, wherein the p-channel and the n-channel extend in parallel, the p-channel has a length of at least 6 μm, and the n-channel has a length of at least 2 μm.

9. A manufacturing method of a thin film transistor by positioning a transistor device so that at least one channel is put in the two-dimensional crystal portion of the crystal silicon array according to claim 1.

10. A manufacturing method of two thin film transistors by positioning transistor devices so that a p-channel and an n-channel are put in the two-dimensional crystal portion of the crystal silicon array according to claim 1.
